(19) United States
(12) Patent Application Publication
(10) Pub. No.: US 2013/0319330 A1
(43) Pub. Date: Dec. 5, 2013

(54) LIQUID FEEDING DEVICE AND RESIST DEVELOPING DEVICE

(71) Applicants: Hideo Kobayashi, Shinjuku-ku (JP); Hiromasa Iyama, Shinjuku-ku (JP)

(72) Inventors: Hideo Kobayashi, Shinjuku-ku (JP); Hiromasa Iyama, Shinjuku-ku (JP)

(73) Assignee: HOYA CORPORATION, Shinjuku-ku, Tokyo (JP)

(21) Appl. No.: 13/991,008

(22) PCT Filed: Nov. 21, 2011
(86) PCT No.: PCT/JP2011/076813

§ 371 Date: Aug. 2, 2013

(30) Foreign Application Priority Data
Dec. 2, 2010 (JP) 2010-269548

(51) Int. Cl. H01L 21/027

(52) U.S. Cl. CPC H01L 21/027
USPC 118/712; 118/300

(57) ABSTRACT

A liquid feeding device 1 having a storage part 4 to store a developing solution 11 controlled in a constant temperature state, a holding part 8 for holding a processing target substrate 6 and a feed pipe 5 for flowing the developing solution 11 from the storage part 4 to a discharge part 14 that feeds and sprays the developing solution 11 onto the processing target substrate 6. A pump 16 pressure-feeds the developing solution 11 and a pressure adjuster 20 switches a pressure to the developing solution 11 by the pump 16 to a first pressure, set under a condition that the developing solution 11 discharged from the discharge part 14 reaches a place other than the processing target substrate 6, and a second pressure set under a condition that the developing solution 11 discharged from the discharge part 14 reaches the processing target substrate 6.

### TECHNICAL FIELD

The present invention relates to a liquid feeding device and a resist developing device.

### DESCRIPTION OF RELATED ART

A plurality of liquid feeding devices for processing a processing target material by feeding and spraying a liquid, are conventionally known. As an example the liquid feeding device used in a field of lithography, a resist developing device is known (for example, see patent document 1). The resist developing device is a device of feeding and spraying a developing solution to an already exposed or drawn resist layer (also called simply “exposure” hereafter), to thereby dissolve and remove an unnecessary portion of the resist layer (also called a “resist development” hereafter), and form a resist pattern.

Incidentally, in recent years, a further high resolution of the resist pattern is strongly desired, with a high integration of semiconductor devices and a development of a patterned medium. Then, a method of performing the resist development using the developing solution having a lower temperature than a normal temperature (also called a “low temperature developing method” hereafter), is known as a technique capable of suppressing a deterioration in a shape/quality of the resist pattern and improving a resolution of the resist pattern (for example, see non-patent document 1).

When a difference is larger in solubility (speed) into the developing solution, between a dissolution part and a non-dissolution part formed after exposure of the resist layer, the resist pattern with high contrast can be obtained, and the resolution is improved. Meanwhile, a resist pattern portion (non-dissolution part) which originally does not have to be dissolved at all, is slightly dissolved by the resist development. As a result, in a cross-sectional shape of a pattern obtained after the resist development, a height of the resist pattern is reduced, a vertical shape of a shoulder part is rounded, and a smoothness of a side wall is lessened, and its shape/quality is deteriorated, thus causing a reduction of the resolution.

Therefore, when the resist development is performed using the developing solution having a lower temperature than the normal temperature, the solubility of the resist layer into the developing solution is lowered, and particularly the dissolution of the resist pattern portion (non-dissolution part) is suppressed. As a result, the shape/quality of the resist pattern is improved, and improvement of the resolution is achieved.

Further, similarly in a rinse treatment using a rinse agent executed as needed after development, when the rinse treatment is performed using the rinse agent with the temperature adjusted and controlled to a lower temperature than the normal temperature, the solubility of the rinse liquid into the resist layer is lowered, and particularly the dissolution or swelling of the resist pattern portion (non-dissolution part by the developing solution) is suppressed. As a result, deterioration, etc., of the resist pattern by the rinse treatment is suppressed, and the shape/quality of the resist pattern after development is maintained and the resolution can be maintained.

The “normal temperature” described in this specification means the temperature around 22.5° C. being a general preset temperature of a clean room for manufacturing a semiconductor for example. Accuracy in controlling a temperature in the clean room is generally about a preset value of ±0.1° C. to ±1° C. Accordingly, the temperature of the developing solution used in the low temperature developing method is for example less than 21.5° C. Further, in order to obtain a more excellent resist pattern shape/quality and a high resolution, a temperature of which range does not allow the developing solution to be frozen (a higher temperature than a freezing point), and is practically capable of adjusting and controlling a liquid temperature, can be used. As an example, −10° C.−60° C., or the like described in non-patent document 1, is selected, and the temperature of the developing solution and the rinse agent is controlled in such a selected temp.

### PRIOR ART DOCUMENT

### Patent Document

### Patent Document 1:

Japanese Patent Laid Open Publication No. 1999-154641

### Non-Patent Document

### Non-Patent Document:

XiaoMin Yang et. al. J. Vac. Sci. Technol. B 25(6), November/December 2007p. 2202

### SUMMARY OF THE INVENTION

### Problem to be Solved by the Invention

In recent years, for example, in a field of a nano-imprint, formation of a nano-level fine projection/recess pattern is requested. In order to form such a fine projection/recess pattern with high precision, the temperature of the developing solution is required to be set to a desired specific temperature (lower temperature than the normal temperature), depending on the resolution and quality of the requested resist pattern.

However, as described above, when the temperature of the developing solution is set to be lower than the normal temperature, there is a great difference between the temperature requested for the developing solution, and the temperature of an installation place, etc., of a resist developing device (called an “environment temperature hereafter), thus generating the following inconveniences.

Generally, the resist developing device is configured to store the developing solution in a storage part and control its temperature to a specific (desired) temperature, and feed and spray the developing solution to the resist layer (namely, a processing target substrate, etc.) through a piping for feeding the developing solution (called a “feed pipe” hereafter) from the storage part. In this case, even if the developing solution stored in the storage part is controlled and maintained to a specific temperature, the temperature of the developing solution fed to a base body from the storage part through the feed pipe, is influenced by the environment temperature at a time of feeding and spraying the developing solution to the resist layer, and the temperature is deviated from the desired specific temperature, namely, the temperature is close to the environment temperature. As a result, this fluctuated temperature of the development solution may cause the unstable and non-uniform development. Specifically, projection/recess in development (non-uniformity in plane) is caused in the same (one) processing target material, and the variation in reproduction accuracy in development is caused in different unprocessed materials (plates).

A main object of the present invention is to provide a technique capable of suppressing the temperature fluctuation of a liquid fed to a processing target material or a base body having the processing target material, and capable of stably performing a processing to the processing target material or the base body having the processing target material with high reproduction accuracy, when the liquid is fed and sprayed to the processing target material or the base material having the processing target material with the temperature of the liquid controlled and maintained to the temperature different from the environment temperature.

### Means for Solving the Problem

a first aspect of the present invention provides a liquid feeding device, including:

a storage part configured to store a liquid controlled in a constant temperature state;

a holding part configured to hold a processing target material or a base body having the processing target material to which the liquid stored in the storage part is fed and sprayed;

a feed pipe forming a flow path for flowing the liquid stored in the storage part, and having a discharge part for discharging the liquid flowing through the flow path, and configured to feed and spray the liquid to the processing target material or the base body having the processing target material by discharging the liquid from the discharge part;

a pressure-feeding unit configured to pressure-feed the liquid to be flowed through the flow path formed by the feed pipe; and

a pressure variable unit capable of switching a pressure added on the liquid in the feed pipe by the pressure-feeding unit, to a first pressure set under a condition that the liquid discharged from the discharge part reaches a place other than the processing target material or the base body having the processing target material, and a second pressure set under a condition that the liquid discharged from the discharge part reaches the processing target material or the base body having the processing target material.

A second aspect of the present invention provides the liquid feeding device according to the first aspect, wherein when the liquid is fed and sprayed to the processing target material or the base body having the processing target material held by the holding part, the liquid is fed and sprayed to the processing target material or the base body having the processing target material by performing a first operation of discharging the liquid from the discharge part of the feed pipe after the pressure added on the liquid in the feed pipe by the pressure-feeding unit is set to the first pressure by the pressure variable unit, and a second operation of discharging the liquid from the discharge part of the feed pipe after the pressure added on the liquid in the feed pipe by the pressure-feeding unit, is changed and set to the second pressure from the first pressure by the pressure variable unit.

A third aspect of the present invention provides the liquid feeding device according to the second aspect, wherein in the first operation, a total quantity or more of the liquid remained in the feed pipe is discharged from the discharge part of the feed pipe before the first operation.

A fourth aspect of the present invention provides the liquid feeding device according to the first, second, or third aspect, wherein

the storage part includes a first storage part and a second storage part configured to store the liquid independently from each other;

the feed pipe includes a first feed pipe extracted from the first storage part, a second feed pipe extracted from the second storage part, and a third feed pipe connected to the discharge part; and

the pressure variable unit includes a first pressurizer for pressurizing the liquid stored in the first storage part under the first pressure, a second pressurizer for pressurizing the liquid stored in the second storage part under the second pressure, and a valve for switching the flow path so that the first feed pipe and the second feed pipe are selectively connected to the third feed pipe.

A fifth aspect of the present invention provides the liquid feeding device according to any one of the first to fourth aspects, wherein a temperature detector is provided to the discharge part of the feed pipe or a part of the feed pipe.

A sixth aspect of the present invention provides a resist developing device that performs development by feeding a developing solution to a processing target substrate having a resist layer with a desired specific pattern exposed or drawn thereon, including:

a storage part configured to store a developing solution controlled in a constant temperature state;

a holding part configured to hold the processing target substrate;

a feed pipe forming a flow path for flowing a developing solution stored in the storage part, having a discharge part for discharging the developing solution flowing through the flow path, and configured to feed and spray the developing solution to the processing target substrate by discharging the developing solution from the discharge part;

a pressure-feeding unit configured to pressure-feed the developing solution to be flowed through the flow path formed by the feed pipe; and

a pressure variable unit capable of switching a pressure added on the developing solution in the feed pipe by the pressure-feeding unit, between a first pressure set under a condition that the developing solution discharged from the discharge part reaches a place other than the processing target substrate, and a second pressure set under a condition that the liquid discharged from the discharge part reaches the processing target substrate.

A seventh aspect of the present invention provides the resist developing device according to the sixth aspect, wherein the processing target substrate to which the developing solution is fed and sprayed, is a mold fabricating substrate for the purpose of use for a nano-imprint method.

An eighth aspect of the present invention provides the resist developing device according to the sixth or seventh aspect, including a liquid temperature controller configured to control a temperature of the developing solution stored in the storage part to a temperature different from an environment temperature.

A ninth aspect of the present invention provides the resist developing device according to the sixth, the seventh or eighth aspect, including a liquid temperature controller configured to control the temperature of the developing solution stored in the storage part, to 0° C. or less.

A tenth aspect of the present invention provides the resist developing device according to any one of the sixth to ninth aspects, including at least each one of:

a rinse agent storage part configured to store a rinse agent; and

a feed pipe forming a flow path for flowing the rinse agent stored in the rinse agent storage part, and having a discharge part for discharging the rinse agent flowing through the flow path, and configured to feed and spray the rinse agent to a processing target substrate by discharging the rinse agent from the discharge part.

### Advantage of the Invention

According to the present invention, when the temperature of a liquid is controlled and maintained to a different temperature from the environment temperature, and when the liquid is fed and sprayed to the processing target material or the base body having the processing target material, the temperature fluctuation of the liquid actually fed and sprayed to the processing target material or the base body having the processing target material can be suppressed, and processing can be stably applied with high precision to the processing target material or the base body having the processing target material to which the liquid is fed and sprayed.

### BRIEF DESCRIPTION OF THE DRAWINGS

FIG. 1 is a schematic view showing a structure of a resist developing device as an example of a liquid feeding device.

FIG. 2 is a view showing a structure example of a jacket.

FIG. 3 is a view showing an operation of the resist developing device according to an embodiment of the present invention.

FIG. 4 is a view showing one of modified examples of the present invention.

### DETAILED DESCRIPTION OF THE INVENTION

Detailed explanation is given hereafter for an embodiment of a liquid feeding device according to the present invention in a case of being applied to a resist developing device used in a field of a photolithography, with reference to the drawings.

Note that the liquid feeding device of the present invention can be applied not only to the resist developing device given here, but also to an overall liquid feeding device widely in other field for feeding and spraying a liquid to a processing target material or a base body having the processing target material. For example, for the purpose of decorating and protecting the processing target material or the base body having the processing target material, the liquid feeding device of the present invention can be applied to a coating device for spraying and feeding a liquid coating material. Further, the processing target material or the base body having the processing target material, being the targets to which the liquid is fed and sprayed, are not particularly limited in structure, and objects with various structures can be the processing target material or the base body having the processing target material. For example, if the liquid feeding device is assumed to be the resist developing device, a “substrate having an already exposed or drawn resist layer on a main surface, corresponds to the “base body”.

The embodiment of the present invention will be described in the following order.

1. Structure of the resist developing device as an example of the liquid feeding device

2. Operation of the resist developing device

3. Effect of the embodiment

4. Modified example, etc.

### 1. Structure of the Resist Developing Device

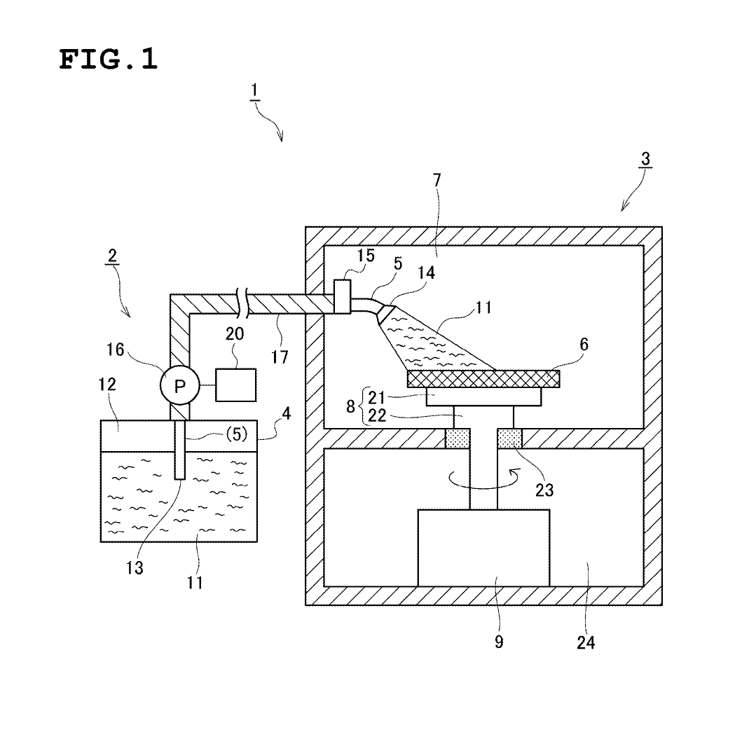

FIG. 1 is a schematic view showing a structure of a resist developing device as an example of a liquid feeding device. A resist developing device 1 shown in the figure roughly includes a developing solution feed part 2, and a development processing part 3. The developing solution feed part 2 is a portion for feeding a developing solution required for development processing performed by the development processing part 3. The developing solution feed part 2 includes at least a storage part 4 for storing the developing solution, and a feed pipe 5 for feeding (transporting) the developing solution. The development processing part 3 is a portion for performing the development processing to a processing target substrate 6 having an already exposed or drawn resist layer on a main surface. The development processing part 3 includes at least a processing chamber 7 having a space for the development processing, a holding part 8 for holding the processing target substrate 6 in this processing chamber 7, and a rotation drive part 9 for rotary-driving the holding part 8. Structures of the developing solution feed part 2 and the development processing part 3 will be more specifically described hereafter.

(Structure of the Developing Solution Feed Part)

Although not shown in detail, for example, the storage part 4 includes a vessel body with an upper part opened, and a lid member for substantially closing the upper part opening of this vessel body, so that an inside of the vessel body is thermally and substantially sealed by this lid member. Namely, the storage part 4 is substantially a sealed type vessel. A suitable amount of a developing solution 11 is contained (stored) in the storage part 4. The solution in a liquid state in an estimated range of a preset temperature, is used as the developing solution 11. In the storage part 4, a space above a liquid face of the developing solution 11, is the space thermally sealed by the above-mentioned lid member (described as an “substantially sealed space” hereafter) 12.

The developing solution 11 stored in the storage part 4, is controlled in a constant temperature state by a liquid temperature controller not shown. As a specific embodiment of the liquid temperature controller, although not shown, for example the following embodiment can be considered: namely, a cooling pipe through which a refrigerant flows, a heater for heating, and a mixer are disposed in contact with the developing solution 11, and the temperature of the developing solution 11 is adjusted and maintained to a previously set temperature (called a “preset temperature” hereafter). In any one of the embodiments employed, the temperature of the developing solution 11 in the storage part 4, is controlled so as to be set within an allowable range (for example within ±0.1° C.) with a desired preset temperature (for example −10° C.) as a central value.

The feed pipe 5 is configured to feed the developing solution 11 stored in the storage part 4, to the processing target substrate 6. The processing target substrate 6 is stationarily placed on the holding part in the processing chamber 7 of the development processing part 3, as a target to which the liquid (developing solution in this embodiment) is fed and sprayed. The processing target substrate 6 being a target of the development processing, is the substrate having an already exposed or drawn resist layer. Further, as an example of the processing target substrate 6, a mold fabricating substrate for the purpose of use for a nano-imprint method, can be given. The mold fabricating substrate for the purpose of use for the nano-imprint (also simply called a “mold substrate” hereafter) is a substrate being a base body of a master mold corresponding to an original mold of a copy mold used in a case of transferring a pattern using the nano-imprint method.

The feed pipe 5 is configured using a long hollow pipe having a cross-sectional circle. One end portion of the feed pipe 5 is a take-in part 13, and the other end portion thereof is the discharge part 14. The take-in part 13 of the feed pipe 5 is opened for introducing the developing solution 11 into the pipe. The discharge part 14 of the feed pipe 5 is opened for discharging the developing solution 11 toward the processing target substrate 6. The discharge part 14 may be a simple one opening, or may have a structure like a shower head having a plurality of small openings. Further, the discharge part 14 may have a structure of generating a spray which ejects the developing solution 11 in a state of mist.

Further, a structure of providing a temperature detector at a part of the feed pipe 5, may also be employed. Thermocouples can be given as an example of the temperature detector. A part of the feed pipe 5 is preferably provided in the discharge part.

The take-in part 13 of the feed pipe 5 is disposed so that the developing solution 11 can be introduced into the storage part 4 of the developing solution feed part 2. Further, the discharge part 14 of the feed pipe 5 is disposed in the processing chamber 11 of the development processing part 3. Then, the take-in part 13 is set as an uppermost stream part, and the discharge part 14 is set as a lowermost stream part, and the feed pipe 5 is installed between them, so as to form the flow path of the developing solution 11. Specifically, the feed pipe 5 is installed so as to introduce the developing solution 11 to an outside from an inside of the storage part 4 in substantially the sealed structure. Further, a lead-out portion of the feed pipe 5 outside of the storage part 4, passes through an outside wall portion of the development processing part 3 and advances into the processing chamber 7, and is installed up to a position facing the holding part 8 in the processing chamber 7. The position facing the holding part 8 is the position where the developing solution 11 discharged from the discharge part 14 of the feed pipe 5, can be fed and sprayed to the processing target substrate 6 held by the holding part 8. In an example shown in the figure, the discharge part 14 positioned at the lowermost stream of the feed pipe 5, is disposed so as to be positioned obliquely upward of the processing target substrate 6 supported by the holding 8, at a position deviated from just above the processing target substrate 6 held by the holding part 8. The discharge part 14 is thus disposed to prevent a droplet of the developing solution 11 dropped from the discharge part 14 of the feed pipe 5, from adhering to a surface (upper surface) of the processing target substrate 6 as one reason, and to prevent the developing solution 11 from being fed to the processing target substrate 6 when the developing solution 11 is discharged under a first pressure described later as another reason.

Further, an open/close valve 15 and a pump 16 are provided in a mid-point of a pipeline of the feed pipe 5. The pump 16 is disposed outside of the storage part 4. Both of the open/close valve 15 and the pump 16 have a function of controlling a flow of the developing solution 11 in the feed pipe 5.

Namely, by setting a pipeline of the feed pipe 5 in an open state, the open/close valve 15 is set in a state of discharging the developing solution from the discharge part 14. Further, by setting the pipeline of the feed pipe 5 in a close state, discharge of the developing solution 11 is inhibited from being discharged from the discharge part 14. The open/close valve 15 has a function of starting or stopping the feed of the developing solution 11.

In feeding the developing solution 11 through the feed pipe 5, a pressure is added on the developing solution 11 by the pump 16, for sucking and transporting the developing solution 11. Namely, the pump 16 is a driving source for sucking the developing solution 11 stored in the storage part 4 into the feed pipe 5, and transporting the sucked developing solution 11 to the discharge part 14 through the feed pipe 5. When the open/close valve 15 is in the open state while the drive of the pump 16 is started or continued, the flow of the developing solution 11 is formed inside of the feed pipe 5. An open/close state of the open/close valve 15, and a drive (on/off) state of the pump 16, can be controlled, for example by a main controller of the resist developing device not shown.

The feed pipe 5 led-out to the outside of the storage part 4, is covered with a heat-insulator jacket 17. The heat-insulator jacket 17 is provided at a part of the feed pipe 5, as an example of a temperature adjustment part. The heat-insulator jacket 17 has a function of adjusting a temperature by being interposed between the feed pipe 15 and its surrounding outside air (atmosphere), and further preferably has a function of keeping the temperature of the developing solution 11 that stays in the feed pipe 5, or the developing solution 11 that moves in the feed pipe 5, in the same temperature (preset temperature) as the temperature in the storage part 4 by making a heating medium flow and circulated around the feed pipe 5. The heat-insulator jacket 17 has a multiple pipe structure (double pipe structure) for example, with the feed pipe 5 as a center.

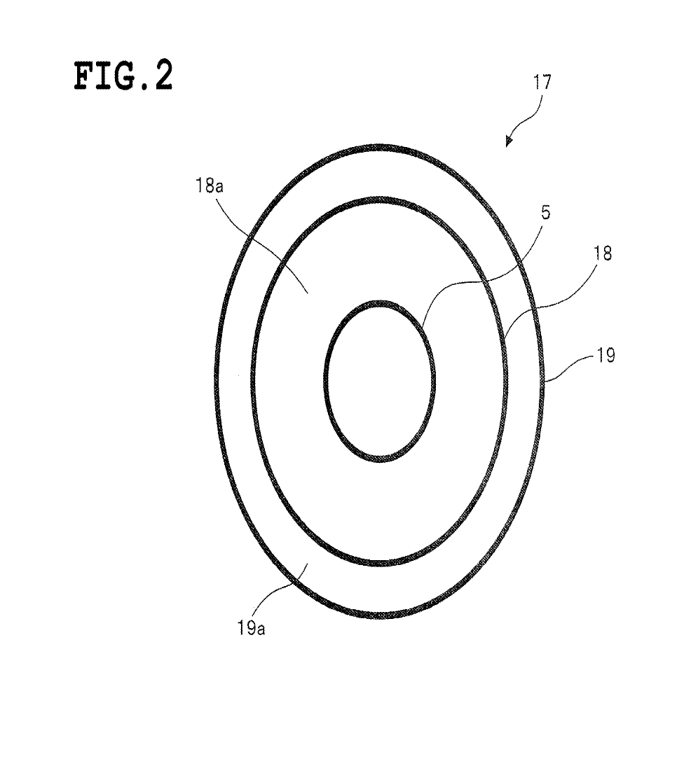

As an example, as shown in FIG. 2, the heat-insulator jacket 17 has a triple pipe structure including the feed pipe 5 therein. The feed pipe 5 is a pipe positioned at an innermost side, with a second pipe 18 having a larger diameter than the diameter of the feed pipe 5 disposed outside thereof, and a third pipe 19 having a larger diameter than the diameter of the second pipe 18 disposed further outside thereof (namely outermost side). In the heat-insulator jacket 17 having such a triple pipe structure, for example a coolant is circulated between an outer peripheral surface of the feed pipe 5 and an inner peripheral surface of the pipe 18, to thereby form a flow path 18a for the heating medium. Further, in order to form a heat insulating layer 19a in the space between the outer peripheral surface of the second pipe 18 and the inner peripheral surface of the third pipe 19, this space is filled with air for example, or preferably is formed into a vacuum sealed structure.

The heat insulator jacket 17 is provided in a state of covering the feed pipe 5, in a form continuous to a piping portion extending from the storage part 4 to the processing chamber 7 of the development processing part 3, and to a piping portion extending to the discharge part 14 facing the holding part 8 in the processing chamber 7. Also, the heat insulator jacket 17 is provided in a state of covering the feed pipe 5 excluding a fitting part of the open/close valve 15 and the fitting part of the pump 16, at the piping portion extending from the storage part 4 to the processing chamber 7 of the development processing part 3. Further, the heat insulator jacket 17 is provided inside of the processing chamber 7, with the fitting part of the open/close vale 15 as a terminal position.

Incidentally, a pressure adjuster 20 is connected to the pump 16. The pressure adjuster 20 has a function of adjusting a pump pressure of the pump 16.

Further specifically, the pump 16 is provided as an example of a pressure-feeding unit for pressure-feeding the developing solution 11, when the developing solution 11 is fed and sprayed to the processing target substrate 6 through the feed pipe 5. Wherein, the pressure feeding device 20 is provided as an example of a pressure variable unit capable of switching the pressure added on the developing solution 11 in the feed pipe 5 by the pump 16, to the previously set first pressure and second pressure.

The “first pressure” and the “second pressure” will be described hereafter.

The first pressure is the pressure set under a condition that the developing solution 11 discharged from the discharge part 14 of the feed pipe 5 reaches a place other than the processing target substrate 6. Meanwhile, the second pressure is the pressure set under a condition that the developing solution 11 discharged from the discharge part 14 reaches the processing target substrate 6.

In this embodiment, in order to vary a flying distance of the developing solution 11 discharged from the discharge part 14 in a plane parallel to the processing target substrate 6 held by the holding part 8, a sufficient and suitable difference is made between the first pressure and the second pressure. Specifically, the first pressure is set to be relatively low, to thereby intentionally make a short flying distance of the developing solution 11 so that the developing solution 11 does not reach the processing target substrate 6. Meanwhile, the second pressure is set to be relatively high, to thereby intentionally make a long flying distance of the developing solution 11 so that the developing solution 11 reaches the processing target substrate 6.

(Structure of the Development Processing Part)

As described above, the development processing part 3 includes the processing chamber 7, the holding part 8, and the rotation drive part 9. Among them, the holding part 8 is composed of a table 21 supporting the processing target substrate 6 in a fixed state, and a spindle shaft 22 connected to the table 21.

The table 21 is configured to horizontally support the processing target substrate 6 from a lower surface side. A support structure of the processing target substrate 6 by the table 21 may be an abutment system using a pin, etc.

The spindle shaft 22 is a shaft for rotary-driving the table 21 by a driving power of the rotation drive part 9. The spindle shaft 22 is disposed in a state of passing through a bottom wall of the processing chamber 7 partitioned by box-shaped walls. Further, a seal member 23 is provided at a through portion of the spindle shaft 22 on the bottom wall of the processing chamber 7. The seal member 23 is configured to prevent a leak of a liquid (including the developing solution 11) to outside of the processing chamber 7 from the through portion of the spindle shaft 22, while accepting a rotation of the spindle shaft 22. The rotation drive part 9 is disposed in a lower chamber 24 divided from the processing chamber 7 by a wall. Although not shown, the rotation drive part 9 is configured, for example using a motor being a driving source of a rotation, and a driving power transmission mechanism (gear train, etc.) that transmits a driving power of the motor to the spindle shaft 22.

Although not shown in FIG. 1, the resist developing device 1 includes a rinse agent feed part, as an additional function part. The rinse agent feed part is the function part for feeding a rinse agent to the processing target substrate 6 after development applied thereto, and applying a rinse treatment thereto.

Here, for the same purpose as the case of setting the liquid temperature of the developing solution 11 to the temperature different from the environment temperature, the temperature of the rinse agent may be set and controlled to the temperature different from the environment temperature. Namely, the temperature of the rinse agent may be set to the same temperature as the preset temperature of the developing solution 11, or may be set to the temperature different from the preset temperature of the developing agent 11. In this case, the rinse agent feed part may have completely the same structure as the structure of the developing solution feed part 2.

Further, the resist developing device 1 may include a second rinse agent feed part as the additional function part. The second rinse agent feed part is the function part for feeding a second rinse agent to the processing target substrate 6 after end of the rinse treatment applied thereto, and performing the second rinse treatment thereto. The second rinse agent feed part may have completely the same structure as the structure of the developing solution feed part 2. Here, the temperature of the second rinse agent is preferably set to the same temperature as the environment temperature, or to a higher temperature than a dew-point temperature determined by the environment temperature and a humidity in this environment. When the temperature of the rinse agent is set to not more than the dew-point temperature in a drying treatment subsequently performed after the rinse treatment, dew condensation occurs on the processing target substrate 6 simultaneously with a stop of the feed/spray of the rinse agent to the processing target substrate 6, and due to this drying treatment, a collapse of the resist pattern occurs by a capillary force generated between resist patterns when dew condensation water is evaporated and dried. Therefore, the temperature of the second rinse agent is set to a higher temperature than the dew-point temperature. This is because the collapse of the resist pattern and generation of a stain due to the dew condensation can be prevented.

As described above, explanation is given for an example of setting the temperature of the developing solution 11 and the temperature of the first rinse agent to be lower than the dew-point temperature determined from the environment temperature and humidity, and setting the temperature of the rinse agent used for the second rinse treatment immediately before drying, to a higher temperature than the dew-point temperature. Here, the temperature is not limited to the above case, and for example, it is also acceptable that the temperature of the rinse agent used for the first rinse treatment is set to be higher than the dew-point, and subsequently the drying treatment is performed, or the temperature of the rinse agent used for the first and second rinse treatments is set to a lower temperature than the dew-point, and the temperature of the rinse agent used for the third rinse agent immediately before the drying treatment, is set to a higher temperature than the dew-point. When using the rinse agent having the higher temperature than the temperature of the developing solution immediately after stop of the feed of the developing solution, an unsuccessful development occurs in some cases. However, such an unsuccessful development can be prevented if the rinse agent having different temperatures is used step by step from a lower temperature equivalent to the temperature of the developing solution.

Alternately, immediately before the drying treatment or during the drying treatment, a gas (dried nitrogen gas and dried air, etc.) with the temperature set to a higher temperature than the dew-point and not containing water, may be fed and sprayed to the processing target substrate 6, instead of using the rinse agent with the temperature set to a higher temperature than the dew-point.

### 2. Operation of the Resist Developing Device

An operation of the resist developing device 1 having the above-mentioned structure will be described next. The operation of the resist developing device 1 is performed based on a control command from the above-mentioned main controller.

First, regarding the developing solution feed part 2, the temperature of the developing solution 11 stored in the storage part 4 is maintained to a desired preset temperature (for example −10° C.) by controlling the temperature of the developing solution 11 stored in the storage part 4 by a liquid temperature controller (not shown).

Meanwhile, regarding the development processing part 3, the processing target substrate 6 for a test to select the first and second pressures is placed on the table 21 of the holding part 8, and thereafter is fixed thereto and supported thereby. Next, the rotation drive part 9 is driven to rotate the spindle shaft 22. Thus, the table 21 supporting the processing target substrate 6 is rotated together with the spindle shaft 22.

In such a state, the pump 16 is driven, and simultaneously or immediately thereafter, the open/close valve 15 on the feed pipe 5 is set in the open state, to thereby take-in the developing solution 11 in the storage part 4 into the feed pipe 5 which has been empty, and through this feed pipe 5, the developing solution 11 is sent toward the discharge part 14. Then, the developing solution 11 is discharged from the discharge part 14 which is positioned at the lowermost stream of the feed pipe 5.

At this time, the pressure added on the developing solution 11 in the feed pipe 5 by the pump 16, is adjusted by the pressure adjuster 20, so that the developing solution 11 discharged from the discharge part 14 of the feed pipe 5 reaches a surface of the rotating processing target substrate 6 (resist layer), to thereby set the second pressure. At this time, the second pressure is set to make the developing solution 11 reach the plane area of the processing target substrate including at least a central part of the processing target substrate 6. Then, the developing solution 11 is evenly fed over the whole body of the processing target substrate 6 by a centrifugal force caused by the rotation of the processing target substrate 6, thus applying development processing to the resist layer on the surface of the processing target substrate 6.

Incidentally, when the resist layer is formed using a negative resist, in the film formation and exposure of the resist film applied to the processing target substrate 6, a subsequently exposed or drawn part becomes an insoluble part, thus forming the resist pattern. Meanwhile, when the resist layer is formed using a positive resist, a subsequently exposed part becomes a soluble part, thus forming the resist pattern.

After the second pressure is determined as described above, the discharge of the developing solution 11 from the discharge part 14 is continued while the open/close valve 15 is kept in the open state and the pump 16 is operated. Then, the pressure added on the developing solution 11 in the feed pipe 5 by the pump 16 is adjusted by the pressure adjuster 20 so that the developing solution 11 discharged from the discharge part 14 of the feed pipe 5 does not reach the surface (resist layer) of the rotating processing target substrate 6, to thereby set the first pressure. After the second and first pressures are determined, the open/close valve 15 is switched to the close state from the open state, to thereby stop the feed/spray of the developing solution 11 from the discharge part 14, and simultaneously or immediately thereafter, the drive of the pump 16 is stopped.

Next, the second pressure and the first pressure are adjusted and set based on a completely similar procedure as the procedure of the developing solution feed part 2, in a rinse agent feed part (a single number of, or plural numbers of rinse agent feed parts) not shown. Further, in the rinse agent feed part for the rinse treatment performed immediately before drying (including a case of the rinse treatment immediately after the development processing, or a case of the rinse treatment after passing through a single number of or plural numbers of rinse treatments), the pressure corresponding to the second pressure is adjusted and set based on a completely similar procedure as the procedure of the developing solution feed part 2.

After the second and first pressures are determined, the open/close valve 15 is switched to the close state from the open state, to thereby stop the feed/spray of the rinse agent from the discharge part 14, and simultaneously or immediately thereafter, the drive of the pump is stopped.

Next, when setting of the second pressure and the first pressure in all rinse agent feed parts are ended, drying treatment is performed to the processing target substrate 6 for test, and thereafter the drive of the rotation drive part 9 is stopped. Thus, rotations of the spindle shaft 22 and the table 21, namely the rotation of the processing target substrate for test is stopped.

Regarding the above-mentioned developing solution 11 and a single number of, or plural numbers of rinse agents, the discharge/spray of the developing solution 11 (including the rinse agent) is maintained in a stop state by the open/close valve 15, in a period from end of a work of determining the second and first pressures until start of the development processing applied to a first processing target substrate 6 for forming the resist pattern after actually passing through the exposure or drawing. Therefore, the developing solution 11 remains inside of the feed pipe 5 in this period. Then, when the development processing of the first processing target substrate 6 is started, the developing solution 11 remained in the feed pipe 5 heretofore is discharged from the discharge part 14 of the feed pipe 5.

Here, the temperature of the developing solution 11 (including the rinse agent) remained in the feed pipe 5, is maintained to approximately the same as the temperature of the developing solution 11 in the storage part 4 by the temperature insulator jacket 17. Therefore, the temperature of the developing solution 11 discharged from the discharge part 14 of the feed pipe 5 by re-starting the development processing, is supposed to be the temperature equivalent to the temperature of the developing solution 11 in the storage part 4.

However, actually a part not completely covered by the temperature insulator jacket 17, namely, the open/close valve 15 and a piping portion of the feed pipe 5 on the downstream side thereof, or the pump 16 is strongly influenced by the environment temperature, compared with a part covered by the temperature insulator jacket 17. Therefore, the temperature of the developing solution 11 remained in the feed pipe 5 (including the rinse agent) is partially deviated from the desired preset temperature, and is close to the environment temperature. Further, even after a total amount of the developing solution 11 (including the rinse agent) remained in the feed pipe 5 is discharged from the discharge part 14, namely, even if a new developing solution 11 with the liquid temperature set to the sufficiently stable value, is introduced into the feed pipe 5 from the storage part 4, the temperature of a part of the feed pipe 5 not completely covered by the temperature insulator jacket 17 or the open/close valve 15 or the pump 16, etc., is close to the environment temperature. Accordingly, when the new developing solution 11 passes through these parts, the liquid temperature thereof is deviated from the preset value.

Further, when a remaining time of the developing solution 11 in the feed pipe 5 is prolonged, namely when a larger interval is formed between processing of the processing target substrate 6 and the next processing of the processing target substrate 6, a degree of a deviation becomes larger in the temperature of the developing solution 11. Particularly, when the developing solution 11 is not remained in the feed pipe 5 on the downstream side of the fitting part of the open/close valve 15 (empty state), the temperature of the feed pipe 5 is rapidly close to the environment temperature, and therefore the temperature of the developing solution 11 passing therethrough can largely exceed a suitable temperature range in some cases. Further, if all piping portions of the feed pipe 5 are covered by the jacket 17, a facility becomes extremely large, thus further increasing a facility cost.

Here, the above-mentioned “suitable temperature range” means the range requested in the developing solution 11 actually fed to the processing target substrate 6, for obtaining a pattern satisfying a desired resolution by the development processing.

In order to cope with a case that the temperature of the developing solution 11 exceeds the suitable temperature range and there is a fluctuation in the temperature, the main controller of the resist developing device 1 controls the operation of the resist developing device 1 so as to perform a first operation and a second operation described hereafter.

Namely, when the developing solution 11 is fed to the processing target substrate 6 held by the holding part 8, under a control by the main controller, an operation of discharging the developing solution 11 from the discharge part 14 of the feed pipe 5 is performed as the first operation, in a state that the pressure added on the developing solution 11 in the feed pipe 5 by the pump 16, is set to the first pressure by the pressure adjuster 20. Further, under the control by the main controller, an operation of discharging the developing solution 11 from the discharge part 14 of the feed pipe 5 is performed as the second operation, in a state that the pressure added on the developing solution 11 in the feed pipe 5 by the pump 16, is set and switched to the second pressure from the first pressure by the pressure adjuster 20.

An operation control by the main controller described above, is performed every time the processing target substrate 6 held by the holding part 8 is replaced.

When the above-mentioned operation control is applied, more specifically the first operation and the second operation are performed based on the following procedure. Here, the operation of the resist developing device 1 is described on the assumption that the developing solution 11 is remained in the piping portion on the downstream side of the fitting part of the open/close valve 15 in a piping direction of the feed pipe 5.

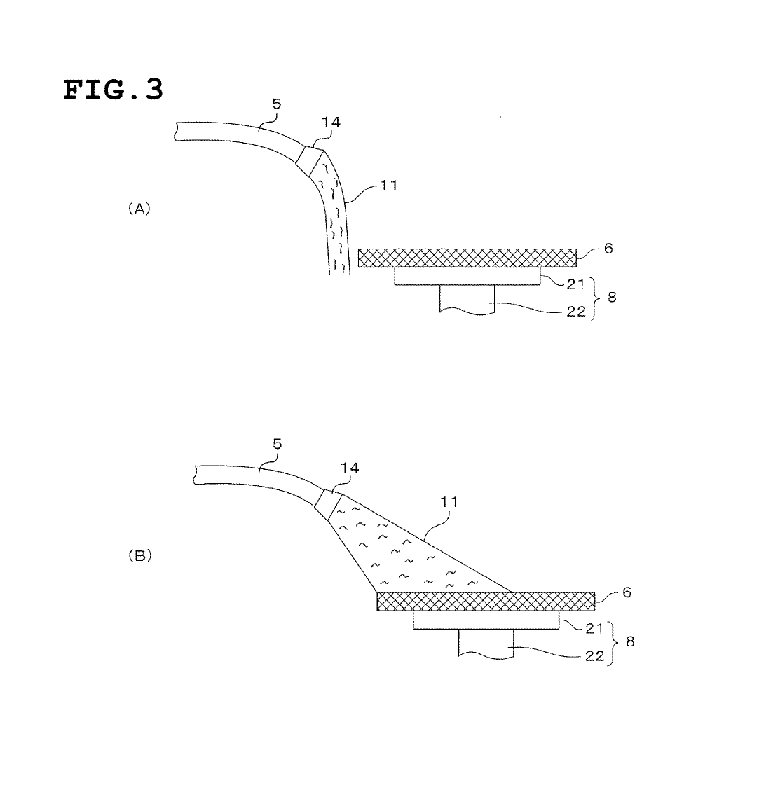

First, prior to performing the development processing to the next processing target substrate 6, the pressure added on the developing solution 11 in the feed pipe 5, is set to the first pressure by the pressure adjuster 20. Namely, the pressure added on the developing solution 11 in the feed pipe 5, is set to be low. In this state, when the open/close valve 15 is switched to the open state from the close state, even if the developing solution 11 is discharged from the discharge part 14 of the feed pipe 5, as shown in FIG. 3(A), the developing solution 11 discharged from the discharge part 14 does not reach the processing target substrate 6, and flows down in a space in front of the processing target substrate 6. Accordingly, the developing solution 11 with the liquid temperature deviated from the preset temperature, is not fed to the processing target substrate 6. This is the first operation.

In the first operation, a larger liquid amount than a total amount of the developing solution remained in the feed pipe 5 before staring the first operation (also called a “remained developing solution”), is preferably discharged from the discharge part 14 of the feed pipe 5. Specifically, in the above-mentioned first operation, it is preferable to discharge the developing solution 11 of an amount required for making the temperature of the part not covered by the heat insulator jacket 17 reach the temperature approximately equivalent to the temperature of the developing solution 11 in the storage part 4, by a heat exchange with the developing solution 11 flowing through the feed pipe 5.

Thereafter, in a stage of discharging the developing solution 11 of a specific amount containing the remained developing solution, the pressure added on the developing solution 11 in the feed pipe 5 by the pump 16 is set and switched to the second pressure from the first pressure by the pressure adjuster 20. Namely, the pressure added on the developing solution 11 in the feed pipe 5 is set to be high. Then, the flying distance of the developing solution 11 is extended, with an increase of the pressure. Therefore, as shown in FIG. 3(B), the developing solution 11 discharged from the discharge part 14 reaches the processing target substrate 6. Namely, the developing solution 11 is fed to the processing target substrate 6. This is the second operation. In this case, the developing solution 11 fed to the processing target substrate 6 is in a state controlled to a constant temperature in the storage part 4, not containing the remained developing solution.

Further, when some part of the feed pipe 5 is equipped with the temperature detector, the system is as follows: namely, when the temperature of the developing solution 11 does not reach a specific value, or even if it reaches the specific value, and when a liquid temperature fluctuation is larger than an accuracy of the temperature detector, the pressure added on the developing solution 11 is switched to the first pressure, and meanwhile, when the temperature of the developing solution 11 reaches the specific value, and when the liquid temperature fluctuation is smaller than the accuracy of the temperature detector, the pressure added on the developing solution 11 is switched to the second pressure. With this structure, the solution with the well-controlled temperature can be fed and sprayed to the processing target substrate.

### 3. Effect of the Embodiment

According to the resist developing device of the present invention, the following effect can be obtained.

Namely, the resist developing device of the present invention has a structure in which the pressure added on the developing solution 11 in the feed pipe 5 by the pump 16, can be switched to the first pressure and the second pressure by the pressure adjuster 20, and by this switch of the pressure, only the developing solution 11 with the temperature accurately controlled to the desired preset temperature, can be fed to the processing target substrate 6. Therefore, even when the temperature of the developing solution 11 remained in the mid-point of the pipeline of the feed pipe 5, and the temperature of the feed pipe 5 covered by the temperature insulator jacket 17, are deviated from the preset temperature under the influence of the environment temperature, the liquid temperature is stable as the preset temperature, and the developing solution 11 without temperature fluctuation can be fed to the processing target substrate 6. Accordingly, an uneven dissolution, etc., in development caused by the temperature fluctuation of the developing solution 11 can be suppressed. Therefore, the resist pattern with high reproduction accuracy can be stably formed, and the resist pattern can be formed while stably maintaining a desired resolution.

Particularly, when the time from the development processing of an immediate preceding processing target substrate 6 to the development processing of the next processing target substrate 6 (called a “processing suspension time” hereafter), is not a constant interval, the development processing can be performed without feeding or spraying the developing solution 11 with a liquid temperature largely deviated from a setting temperature or having a large temperature fluctuation, by sequentially performing the above-mentioned first operation and second operation. Therefore, in a plurality of processing target substrates 6, the development processing can be stably performed with good reproduction accuracy.

For example, when switching of manufacturing lots, etc., and change of setup operation, etc., are required, or when maintenance, etc., of the resist developing device 1 is required, these cases are considered to be the case that the processing suspension time is longer than an allowable time.

Further, particularly, when the processing target substrate 6 is a mold manufacturing substrate for the use of the nano-imprint method, the small temperature fluctuation of the developing solution 11 fed and sprayed to the processing target substrate 6 makes it possible to form a fine projection/recess pattern with high resolution and good reproduction accuracy. This is because a size of the pattern formed on the mold manufacturing substrate for the purpose of use for the nano-imprint method, is nano-order (for example about 10 nm or not more than 10 nm), which is closed to a resolution limit of the resist itself, and extremely slight fluctuation of the temperature of the developing solution has a direct influence on the resolution of the resist.

Particularly, as the temperature of the developing solution is largely deviated from the environment temperature (normal temperature), for example, as the temperature of the developing solution is set in 0° C. or less condition, the effect appears remarkably when the development processing is performed. In such a state, if the above-mentioned structure of the resist developing device 1 is employed, the developing solution 11 discharged from the discharge part 14 can be fed to the processing target substrate 6 after the temperature of the developing solution 11 surely reaches a desired and specific low temperature of 0° C. or less. Therefore, when the resist development is applied to the mold manufacturing substrate as the processing target substrate 6 for the purpose of use for the nano-imprint, formation of the extremely fine projection/recess pattern of the nano-level can be realized with high resolution and high reproduction accuracy.

### 4. Modified Example, Etc

The technical range of the present invention is not limited to the above-mentioned embodiment, and includes a form with various modifications and improvements added thereto, in a range capable of deriving a specific effect obtained by constituting features of the invention and a combination of them.

For example, the above-mentioned embodiment provides the structure in which the developing solution 11 is not fed to the processing target substrate 6 in such a way that the developing solution 11 discharged from the discharge part 14, flows down in front of the processing target substrate 6, when the pressure added on the developing solution 11 in the feed pipe 5 by the pump 16, is set to be relatively low. However, the present invention is not limited thereto, and the following structure is also acceptable. Namely, when the pressure added on the developing solution 11 in the feed pipe 5 is set to be relatively high, the developing solution 11 is not fed to the processing target substrate 6 in such a way that the developing solution 11 discharged from the discharge part 14 jumps over the processing target substrate 6. In this case, when the developing solution 11 jumps over the processing target substrate 6, an auxiliary mechanism is required so that the developing solution 11 is not fed and sprayed at all to the processing target substrate 6. As an example of the auxiliary mechanism, when the pressure added on the developing solution 11 is set to be relatively high (namely, when the pressure of allowing the developing solution 11 to jump over the processing target substrate 6 is set), the mechanism is as follows: namely, a cover plate is disposed in an upper part of the processing target substrate, for blocking the feed and spray of the developing solution to the processing target substrate. Incidentally, if satisfying a condition that the developing solution 11 discharged from the discharge part 14 reaches a place other than the processing target substrate 6, the pressure at this time may be either low or high, compared with the pressure at the time of actually feeding the developing solution 11 to the processing target substrate 6.

Further, the above-mentioned embodiment shows an example of the pressure adjuster 20 for adjusting a pump pressure of the pump 16, as constituting the pressure variable unit. However, in addition to this structure, the following structure may also be employed: for example, a throttle valve is provided in the mid-point of the pipeline of the feed pipe 5, and by adjusting an opening degree of this throttle valve, the pressure added on the developing solution 11 in the feed pipe 5 can be switched to the first pressure and the second pressure. When this structure is employed, the pressure added on the developing solution 11 in the feed pipe 5 is set to be relatively low, by setting the opening degree of the throttle valve to be relatively small, in performing the first operation. Further, in performing the second operation, the pressure added on the developing solution 11 in the feed pipe 5 is set to be relatively high, by setting the opening degree of the throttle valve to be relatively large. Thus, even when the pump pressure of the pump 16 is set to the same, the flying distance of the developing solution 11 becomes short by opening the throttle valve with small opening degree in performing the first operation, and the flying distance of the developing solution 11 becomes long by enlarging the opening degree of the throttle valve in performing the second operation. Accordingly, a similar effect as the effect of the above-mentioned embodiment can be obtained.

Further, the above-mentioned embodiment shows the example of the pressure adjuster 20 for adjusting the pump pressure of the pump 16, as constituting the pressure variable unit. However, in addition to this structure, the following structure may also be employed: for example, the storage part 4 is formed into a sealed type vessel, and a pressurizer is provided in the storage part 4 instead of the pump 16, and by adjusting the pressurized pressure, the pressure added on the developing solution 11 in the feed pipe 5 can be switched to the first pressure and the second pressure. When this structure is employed, the pressure added on the developing solution 11 in the feed pipe 5 is set to be relatively low by setting the pressure of a pressurizing feed unit of the storage part 4 to be relatively small, in performing the first operation. Also, the pressure added on the developing solution 11 in the feed pipe 5 is set to be relatively high by setting the pressure of the pressurizing feed unit of the storage part 4 to be relatively large, in performing the second operation. Thus, the flying distance of the developing solution 11 becomes short because the pressurizing feed pressure is suppressed to be small in the first operation, and the flying distance of the developing solution 11 becomes long because the pressurizing feed pressure is large in the second operation. Accordingly, a similar effect as the effect of the above-mentioned embodiment can be obtained.

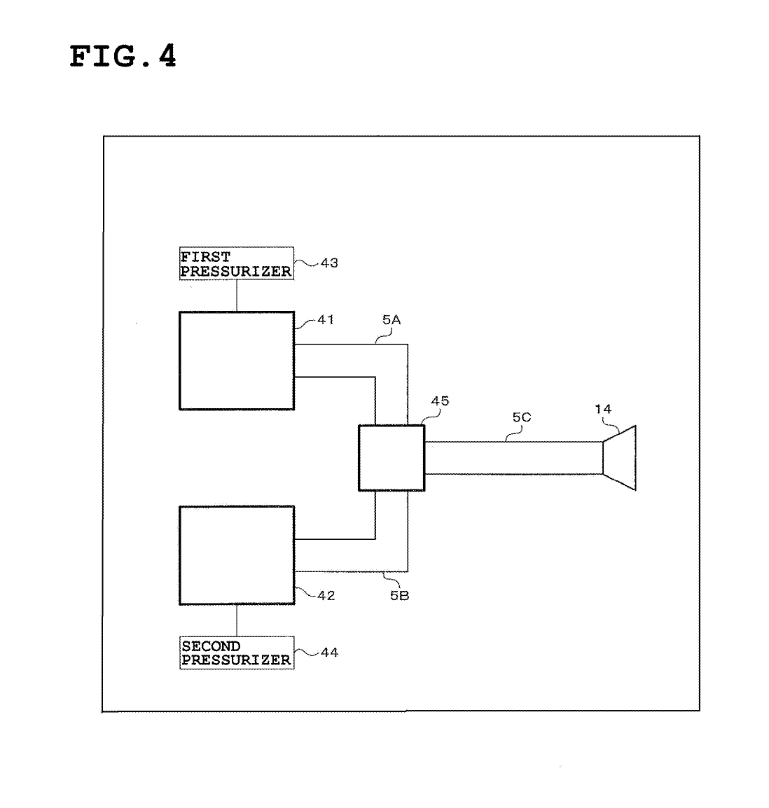

Further, the above-mentioned modified example shows a case that one pressurizing feed unit is provided to one storage part 4, as constituting the pressure variable unit, to thereby adjust the pressure of the pressurizing feed unit. However, in addition, an example as shown in FIG. 4 for example, can also be considered. Namely, two storage parts 41, 42 are formed into the sealed type pressurizing vessels, and the first pressure and the second pressure are added on the storage parts 41 and 42 respectively, by the first pressurizer 43 and the second pressurizer 44. Then, feed pipes 5A, 5B drawn from each of the storage parts 41, 42, and a feed pipe 5C connected to the discharge part 14, are connected to a valve 45 being a three-way valve for example. In this structure, the valve 45 switches the flow path so that the feed pipe 5A and the feed pipe 5B are selectively connected to the feed pipe 5C. With this mechanism, the structure capable of switching the pressure added on the developing solution 11 in the feed pipe 5 to the first pressure and the second pressure, may be employed. When this structure is employed, the pressure added on the developing solution 11 in the feed pipe 5 is set to be relatively low by connecting the feed pipe 5A drawn from the first storage part 41 in which the pressure of the pressurizing feed unit is set to be relatively small, and the feed pipe 5C connected to the discharge part 14, in performing the first operation. Also, the pressure added on the developing solution 11 in the feed pipe 5 is set to be relatively high by connecting the feed pipe 5B drawn from the second storage part 42 in which the pressure of the pressurizing feed unit is set to be relatively large, and the feed pipe 5C connected to the discharge part 14 in performing the first operation. Thus, the flying distance of the developing solution 11 becomes short because the pressurizing feed pressure is suppressed to be small in performing the first operation, and the flying distance of the developing solution 11 becomes long because the pressurizing feed pressure is large in performing the second operation. Accordingly, the similar effect as the effect of the above-mentioned embodiment can be obtained.

Further, according to the above-mentioned structure, the following effect can be obtained. Since two storage parts 4 are prepared in advance and the first pressure and the second pressure are always added on each of the storage parts 4, response to the open/close of the valve is speedily performed in discharging the developing solution. Namely, switching is speedily performed in the discharge of the developing solution with different pressures added thereon, and the change of the flying distance of the liquid is speedily performed. Therefore, non-uniform processing in the plane of the processing target substrate, which occurs when the switching is slow, can be prevented.

Further, the liquid feeding device of the present invention can be widely applied to a liquid feeding device for feeding to a target substrate, not only a liquid cooled to a specific temperature and set to a lower temperature than the environment temperature like the above-mentioned developing solution 11, but also a liquid heated to a specific temperature and set to a higher temperature than the environment temperature, or a liquid controlled to be a constant temperature in a range of a normal temperature (or the environment temperature).

Further, in terms of a generic concept, the liquid feeding device of the present invention (including the resist developing device) is the device capable of executing the first operation of not allowing the liquid (including the developing solution) discharged from the discharge part of the feed pipe to reach the material (including the processing target substrate), and the second operation of allowing the liquid discharged from the discharge part of the feed pipe to reach the material. Then, as an example of realizing such operations, the pressure variable unit for adding a pressure on the discharged liquid is provided.

### DESCRIPTION OF SIGNS AND NUMERALS

1 Resist developing device
2 Developing solution feed part
3 Development processing part
4 Storage part
5 Feed pipe
6 Processing target substrate
7 Processing chamber
8 Holding part
11 Developing solution
16 Pump
17 Jacket
20 Pressure adjuster

1. A liquid feeding device, comprising:
a storage part configured to store a liquid controlled in a constant temperature state;
a holding part configured to hold a processing target material or a base body having the processing target material to which the liquid stored in the storage part is fed and sprayed;
a feed pipe forming a flow path for flowing the liquid stored in the storage part, and having a discharge part for discharging the liquid flowing through the flow path, and configured to feed and spray the liquid to the processing target material or the base body having the processing target material by discharging the liquid from the discharge part;
a pressure-feeding unit configured to pressure-feed the liquid to be flowed through the flow path formed by the feed pipe; and
a pressure variable unit capable of switching a pressure added on the liquid in the feed pipe by the pressure-feeding unit, to a first pressure set under a condition that the liquid discharged from the discharge part reaches a place other than the processing target material or the base body having the processing target material, and a second pressure set under a condition that the liquid discharged from the discharge part reaches the processing target material or the base body having the processing target material.

2. The liquid feeding device according to claim 1,
wherein when the liquid is fed and sprayed to the processing target material or the base body having the processing target material held by the holding part, the liquid is fed and sprayed to the processing target material or the base body having the processing target material by performing a first operation of discharging the liquid from the discharge part of the feed pipe after the pressure added on the liquid in the feed pipe by the pressure-feeding unit is set to the first pressure by the pressure variable unit, and a second operation of discharging the liquid from the discharge part of the feed pipe after the pressure added on the liquid in the feed pipe by the pressure-feeding unit, is changed and set to the second pressure from the first pressure by the pressure variable unit.

3. The liquid feeding device according to claim 2,
wherein in the first operation, a total quantity or more of the liquid remained in the feed pipe is discharged from the discharge part of the feed pipe before the first operation.

4. The liquid feeding device according to claim 1,
2 or 3, wherein the storage part includes a first storage part and a second storage part configured to store the liquid independently from each other;
the feed pipe includes a first feed pipe extracted from the first storage part, a second feed pipe extracted from the second storage part, and a third feed pipe connected to the discharge part; and
the pressure variable unit includes a first pressurizer for pressurizing the liquid stored in the first storage part under the first pressure, a second pressurizer for pressurizing the liquid stored in the second storage part under the second pressure, and a valve for switching the flow path so that the first feed pipe and the second feed pipe are selectively connected to the third feed pipe.

5. The liquid feeding device according to claim 1, wherein a temperature detector is provided to the discharge part of the feed pipe or a part of the feed pipe.

6. A resist developing device that performs development by feeding a developing solution to a processing target substrate having a resist layer with a desired specific pattern exposed or drawn thereon, comprising:
a storage part configured to store a developing solution controlled in a constant temperature state;
a holding part configured to hold the processing target substrate;
a feed pipe forming a flow path for flowing a developing solution stored in the storage part, having a discharge part for discharging the developing solution flowing through the flow path, and configured to feed and spray the developing solution to the processing target substrate by discharging the developing solution from the discharge part;
a pressure-feeding unit configured to pressure-feed the developing solution to be flowed through the flow path formed by the feed pipe; and
a pressure variable unit capable of switching a pressure added on the developing solution in the feed pipe by the pressure-feeding unit, between a first pressure set under a condition that the developing solution discharged from the discharge part reaches a place other than the processing target substrate, and a second pressure set under a condition that the liquid discharged from the discharge part reaches the processing target substrate.

7. The resist developing device according to the claim 6, wherein the processing target substrate to which the developing solution is fed and sprayed, is a mold fabricating substrate for the purpose of use for a nano-imprint method.

8. The resist developing device according to claim 6, comprising a liquid temperature controller configured to control a temperature of the developing solution stored in the storage part to a temperature different from an environment temperature.

9. The resist developing device according to claim 6, comprising a liquid temperature controller configured to control the temperature of the developing solution stored in the storage part, to 0° C. or less.

10. The resist developing device according to claim 6, comprising at least each one of:
a rinse agent storage part configured to store a rinse agent; and
a feed pipe forming a flow path for flowing the rinse agent stored in the rinse agent storage part, and having a discharge part for discharging the rinse agent flowing through the flow path, and configured to feed and spray the rinse agent to a processing target substrate by discharging the rinse agent from the discharge part.
